(19) United States
(12) Patent Application Publication
(10) Pub. No.: US 2026/0366136 A1
(43) Pub. Date: Nov. 19, 2026

(54) EQUIPMENT FOR MANUFACTURING ELECTRONIC APPARATUS, AND ELECTRONIC APPARATUS

(71) Applicant: Samsung Display Co., Ltd., Yongin-Si (KR)

(72) Inventors: HYUNJAE KIM, Yongin-si (KR); KIBUM KIM, Yongin-si (KR); JAEWAN SEOL, Yongin-si (KR)

(21) Appl. No.: 19/634,478

(22) Filed: Mar. 31, 2026

(30) Foreign Application Priority Data
May 14, 2025 (KR) 10-2025-0062795

(51) Int. Cl. C23C 14/26; C23C 14/24; C23C 14/54; H05B 6/42; H05B 6/44; H10K 59/12

(52) U.S. Cl. CPC C23C 14/26; C23C 14/243; C23C 14/542; H05B 6/42; H05B 6/44; H10K 59/1201

(57) ABSTRACT

Provided is an equipment for manufacturing an electronic apparatus which includes a chamber providing an inner space, a crucible disposed in the inner space, and including a storage unit which stores a deposition material, and a nozzle which sprays the deposition material, and a temperature controller controlling a temperature of the crucible. The temperature controller includes a first heater module which includes a first inductive heating coil and heats at least a part of the crucible, a second heater module which is disposed below the first heater module and on a lateral side surface of the crucible and heats another part of the crucible, and a first reflector which is disposed between the first heater module and the second heater module.

### CROSS-REFERENCE TO RELATED APPLICATIONS

This U.S. non-provisional patent application claims priority under 35 U.S.C. § 119 of Korean Patent Application No. 10-2025-0062795, filed on May 14, 2025, the entire contents of which are hereby incorporated by reference.

### BACKGROUND

The present disclosure herein relates to an equipment for manufacturing an electronic apparatus, and an electronic apparatus including a display panel manufactured by using the equipment.

Deposition equipment plays an essential role in forming a thin film during the manufacturing process of a display apparatus. The deposition equipment heats a deposition material in a high-vacuumed chamber to evaporate the deposition material, and the evaporated deposition material is condensed on a surface of a substrate to form a thin film. In this case, radiant heat generated during a process of heating the deposition material is transferred outside a deposition source, which may lead to an increase in a temperature of a substrate in a display panel. Such a heat transfer causes an increase in the temperature of the substrate, which may result in a deterioration in a deposition quality.

### SUMMARY

The present disclosure provides an equipment for manufacturing an electronic apparatus including an inductive heating type heater which directly heats a crucible, thereby making it possible to suppress an increase in a temperature of a substrate during a formation process of a display panel and provide an electronic apparatus with an improved deposition quality.

An embodiment of the inventive concept provides an equipment for manufacturing an electronic apparatus including: a chamber configured to provide an inner space; a crucible disposed in the inner space, and including a storage unit which stores a deposition material and a nozzle which sprays the deposition material; and a temperature controller configured to control a temperature of the crucible, wherein the temperature controller includes a first heater module which includes a first inductive heating coil and heats at least a part of the crucible, a second heater module which is disposed below the first heater module and on a lateral side surface of the crucible and heats another part of the crucible, and a first reflector which is disposed between the first heater module and the second heater module.

In an embodiment, the temperature controller may further include a temperature measurement unit which is in contact with the crucible and measures the temperature of the crucible.

In an embodiment, the crucible may include two long lateral side surfaces facing each other and two short lateral side surfaces facing each other, a first spacing distance from each of the long lateral side surfaces to the first heater module may be constant in a first direction, and a second spacing distance from each of the short lateral side surfaces to the first heater module may be constant in a second direction.

In an embodiment, the second spacing distance may be greater than the first spacing distance.

In an embodiment, the equipment may further include: a support member configured to support the first heater module; and a fixing pin configured to fix the first heater module to the support member.

In an embodiment, the temperature controller may further include a cooling chamber which accommodates the crucible, the first heater module, and the second heater module, and a second reflector which may be disposed between the cooling chamber and the second heater module.

In an embodiment, the equipment may further include: a third reflector disposed in the inner space, and having a nozzle hole through which the nozzle penetrates; and an angle restriction plate configured to adjust a spraying angle for the deposition material sprayed from the nozzle.

In an embodiment, the first heater module may include a first insulating member which is in contact with a first lateral side surface of the first inductive heating coil, a second insulating member in contact with a second lateral side surface opposed to the first lateral side surface of the first inductive heating coil, a shielding member in contact with the second insulating member, and a cooling jacket including a first cooling passage and is the cooling jacket being in contact with the shielding member, and the first inductive heating coil may include a second cooling passage.

In an embodiment, the second heater module may include a resistive heating coil, and the resistive heating coil may be divided into three regions, which are independently controlled.

In an embodiment, the first inductive heating coil may have a spiral shape extending in a longitudinal direction from a center of the first inductive heating coil.

In an embodiment, the first inductive heating coil may have a spiral shape extending in a transverse direction from a center of the first inductive heating coil in a transverse direction.

In an embodiment, the first inductive heating coil may include a plurality of coils, which are independently controlled.

In an embodiment, the second heater module may include a second inductive heating coil, and the first inductive heating coil and the second inductive heating coil may have a spiral shape extending in a longitudinal direction from a center of each of the coils.

In an embodiment, the second heater module may include a second inductive heating coil, the first inductive heating coil may have a spiral shape extending in a longitudinal direction from a center of the first inductive heating coil, the second inductive heating coil may have a spiral shape extending in a transverse direction from a center of the second inductive heating coil in a transverse direction, the second inductive heating coil may include a plurality of coils, which are independently controlled.

In an embodiment, the second heater module may include a second inductive heating coil, the first inductive heating coil and the second inductive heating coil may have a spiral shape extending in a transverse direction from a center of each of the coils, the first heater module and the second heater module may each include a plurality of coils, which are independently controlled.

In an embodiment of the inventive concept, an equipment for manufacturing an electronic apparatus includes: a chamber configured to provide an inner space; a crucible including a storage unit which stores a deposition material, and a nozzle which sprays the deposition material; a heating unit including a heater which applies heat to the deposition material; a cooling unit configured to alleviate an increase in a temperature of the inner space due to the heat; and an angle restriction plate configured to adjust a deposition region of the deposition material, wherein the heating unit includes a first heater module, a reflector, and a second heater module arranged in that sequence on one side of the crucible along a direction toward a lower side of the crucible, and the first heater module including a first inductive heating coil.

In an embodiment, the second heater module may include a second inductive heating coil, and each of the first inductive heating coil and the second inductive heating coil may have a spiral shape extending in a longitudinal direction from a center of the coil.

In an embodiment, the second heater module may include a second inductive heating coil, the first inductive heating coil may have a spiral shape extending in a longitudinal direction from a center of the first inductive heating coil, and the second inductive heating coil may have a spiral shape extending in a transverse direction from a center of the second inductive heating coil.

In an embodiment, the second heater module may include a second inductive heating coil which is disposed on one lateral side surface of the crucible, and the first inductive heating coil and the second inductive heating coil may have a spiral shape extending in a transverse direction from a center of each of the coils.

In an embodiment of the inventive concept, an electronic apparatus includes: a display module including a substrate, a display element layer, and a circuit element layer the display element layer and circuit element layer being disposed in that sequence on the substrate; and one or more processors configured to provide image data to the display module, wherein at least some portions of the display element layer and the circuit element layer are manufactured by a deposition equipment, wherein the deposition equipment includes a chamber providing an inner space, a crucible disposed in the inner space and including a storage unit which stores a deposition material, and a nozzle which sprays the deposition material, and a temperature controller controlling a temperature of the crucible, wherein the temperature controller includes a first heater module which includes a first inductive heating coil and heats at least a part of the crucible, a second heater module which is disposed below the first heater module and on a lateral side surface of the crucible and heats another part of the crucible, and a reflector which is disposed between the first heater module and the second heater module.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept.

FIG. 1 is a block diagram of an electronic apparatus according to an embodiment.

FIG. 2 is a schematic view of each of various electronic apparatuses according to embodiments.

FIG. 3 is a cross-sectional view illustrating an equipment for manufacturing an electronic apparatus according to an embodiment of the inventive concept.

FIG. 4 is a partially cross-sectional enlarged perspective view of an equipment for manufacturing an electronic apparatus according to an embodiment of the inventive concept.

FIG. 5 is a perspective view illustrating a portion of an equipment for manufacturing an electronic apparatus according to an embodiment of the inventive concept.

FIG. 6 is a plan view illustrating a portion of an equipment for manufacturing an electronic apparatus according to an embodiment of the inventive concept.

FIG. 7 is a cross-sectional view of a display panel according to an embodiment of the inventive concept.

FIG. 8 is a graph showing a temperature increase rate of a crucible according to an embodiment of the inventive concept.

FIG. 9 is a graph showing a temperature decrease rate of a crucible according to an embodiment of the inventive concept;

FIG. 10A is a schematic view describing an arrangement of coils in an equipment for manufacturing an electronic apparatus according to an embodiment of the inventive concept.

FIG. 10B is a schematic view describing an arrangement of coils in an equipment for manufacturing an electronic apparatus according to an embodiment of the inventive concept.

FIG. 10C is a schematic view describing an arrangement of coils in an equipment for manufacturing an electronic apparatus according to an embodiment of the inventive concept.

FIG. 10D is a schematic view describing an arrangement of coils in an equipment for manufacturing an electronic apparatus according to an embodiment of the inventive concept.

FIG. 10E is a schematic view describing an arrangement of coils in an equipment for manufacturing an electronic apparatus according to an embodiment of the inventive concept.

### DETAILED DESCRIPTION

The inventive concept may be implemented in various modifications and have various forms, and specific embodiments are illustrated in the drawings and described in detail in the text. It is to be understood, however, that the inventive concept is not intended to be limited to the particular forms disclosed, but on the contrary, is intended to cover all modifications, equivalents, and alternatives falling within the spirit and scope of the inventive concept.

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element, component, region, layer or section from another element, component, region, layer or section. For instance, a first element could be termed a second element without departing from the scope of the inventive concept. Similarly, a second element could be termed a first element. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

In this specification, it will be understood that “being directly disposed” means that there are no intervening layers, films, regions, plates, or the like between a portion of layers, films, regions, plates, or the like and another portion. For example, “being directly disposed” may mean to be disposed between two layers or two members without using an additional member such as an adhesive member or the like.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display apparatus according to an embodiment will be described with reference to the drawings.

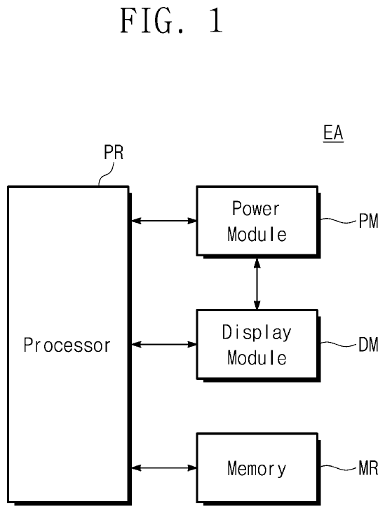

FIG. 1 is a block diagram of an electronic apparatus according to an embodiment.

Referring to FIG. 1, an electronic apparatus EA according to an embodiment may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), or a controller. The processor PR may include one or more processors. In implementations with more than one processor, the processors may work individually, collectively or as part of a collective. For example, as part of a collective two out of three processors may operate together to execute instructions for an application.

The memory MR may store data information for an operation of the processor PR or the display module DM. When the processor PR executes an application stored in the memory MR, image data signals and/or input control signals are transmitted to the display module DM, and the display module DM may process the provided signals and output image information through a display screen. The display module DM may include a display panel which displays images.

The power module PM may include a power conversion module. The power conversion module may convert a power supplied by a power supply module, such as a power adapter or a battery device, to generate a power for an operation of the electronic apparatus EA.

At least one of components of the above-described electronic apparatus EA may be included in a later-described display module according to embodiments or a display apparatus, according to an embodiment, which includes the display module. Additionally, some of the individual modules which are functionally included in one module may be included in the display apparatus and other modules may also be provided separately from the display apparatus. For example, the display apparatus includes the display module DM, and the processor PR, the memory MR, and the power module PM may be provided in the form of other apparatuses within the electronic apparatus EA other than the display apparatus.

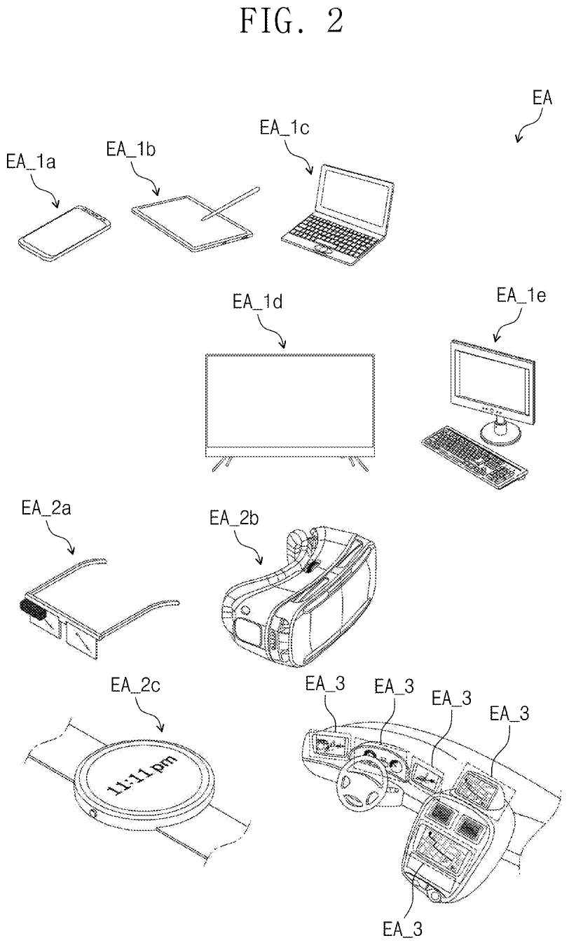

FIG. 2 is a schematic view of each of various electronic apparatuses according to embodiments.

Referring to FIG. 2, various electronic apparatuses including the display module according to an embodiment may include an electronic apparatus for displaying images, such as a smart phone EA_1a, a tablet computer EA_1b, a laptop computer EA_1c, a television EA_1d, and a desktop monitor EA_1e, and a wearable electronic apparatus, such as a smart glasses EA_2a, a head mounted display EA_2b, and a smart watch EA_2c, as well as an automobile electronic apparatus EA_3, such as a center information display (CID) disposed on an instrument panel, a center fascia, or a dashboard of a car, and a room mirror display.

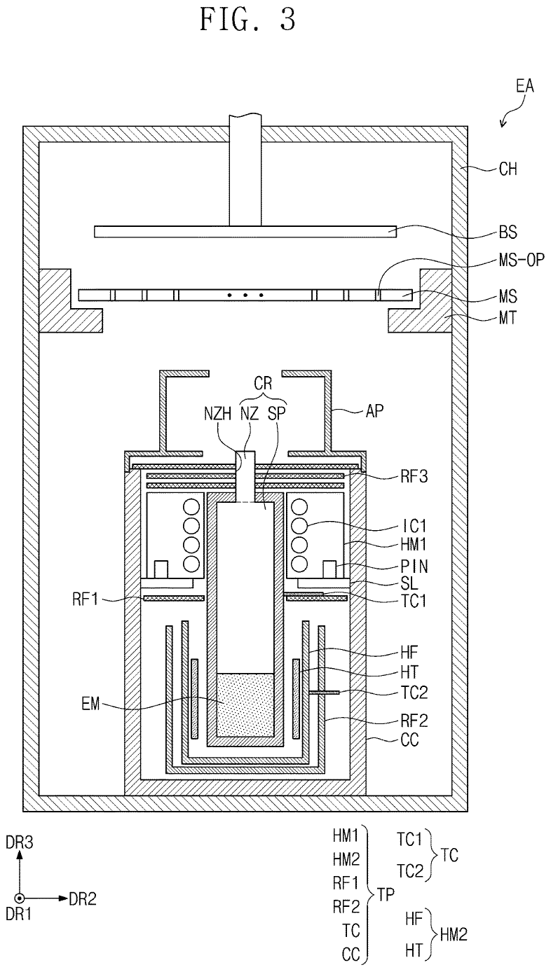

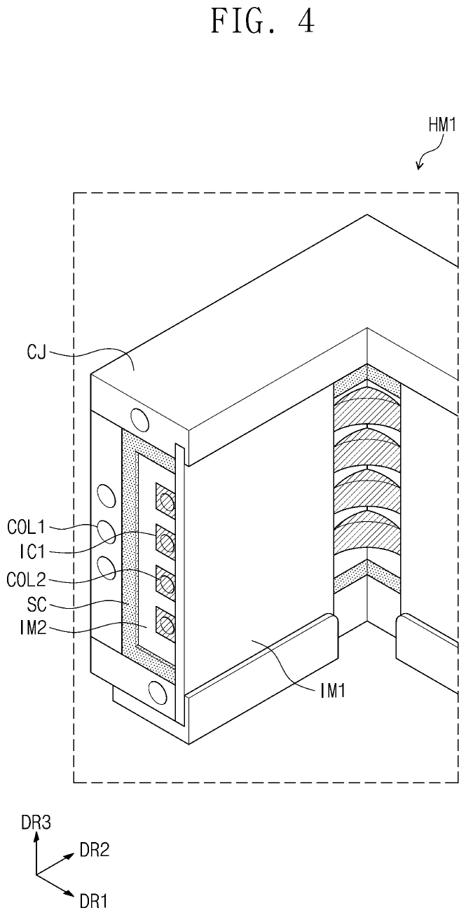

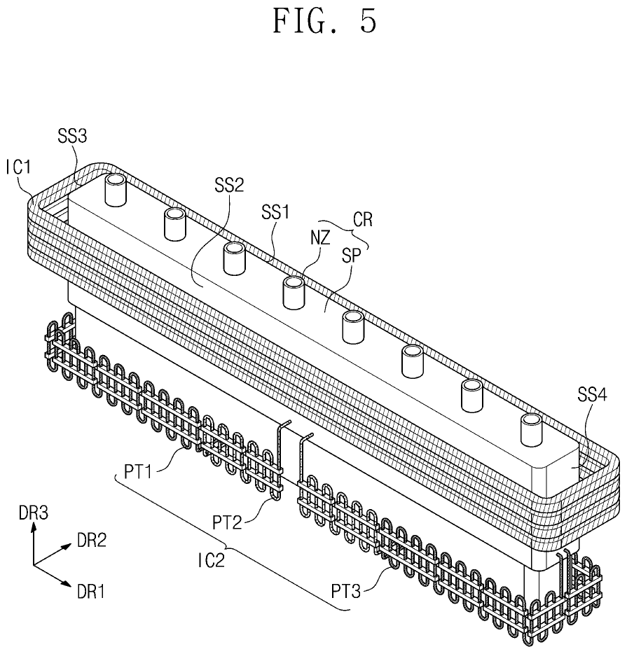

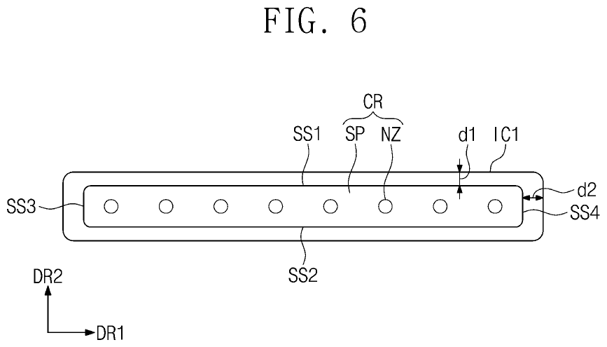

FIG. 3 is a cross-sectional view illustrating equipment for manufacturing an electronic apparatus according to an embodiment of the inventive concept. FIG. 4 is a partially cross-sectional enlarged perspective view of the equipment for manufacturing an electronic apparatus according to an embodiment of the inventive concept. FIG. 5 is a perspective view illustrating a portion of an equipment for manufacturing an electronic apparatus according to an embodiment of the inventive concept. FIG. 6 is a plan view illustrating a portion of an equipment for manufacturing an electronic apparatus according to an embodiment of the inventive concept. For ease of description, FIG. 3 additionally illustrates a base substrate and a mask in addition to an equipment for manufacturing an electronic apparatus.

Referring to FIG. 3, equipment for manufacturing an electronic apparatus EA (or a deposition equipment) according to an embodiment of the inventive concept may include a chamber CH, a crucible CR, and a temperature controller TP. In this case, the equipment for manufacturing an electronic apparatus ED may be an apparatus which deposits an organic material, a conductive material, or the like on a base substrate BS.

The chamber CH may provide an inner space in which a deposition process may be performed. The crucible CR, and the temperature controller TP, which controls a temperature of the crucible, may be disposed in the inner space of the chamber CH.

The crucible CR may provide a deposition material EM to the base substrate BS. The crucible CR may include a storage unit SP, which stores the deposition material EM, and a nozzle NZ which sprays the deposition material EM. The storage unit SP may store and evaporate a predetermined deposition material EM, such as an organic material or a conductive material, and the nozzle NZ may spray the evaporated deposition material EM toward a mask MS. Specifically, the deposition material EM stored in the storage unit SP may be heated, vaporized, and sprayed toward the mask MS via the nozzle NZ. Accordingly, the evaporated deposition material EM may be deposited on the base substrate BS through the mask MS.

Although not illustrated, the deposition equipment EA may further include a conveyance means which moves the crucible CR in horizontal directions DR1 and DR2.

The temperature controller TP may include a first heater module HM1, a second heater module HM2, and a first reflector RF1.

Referring to FIGS. 4 and 5, the first heater module HM1 may include a first inductive heating coil IC1, a first insulating member IM1, a second insulating member IM2, a shielding member SC, and a cooling jacket CJ. The first heater module HM1 may heat at least a part of the crucible CR.

The first inductive heating coil IC1 may heat an upper region of the crucible CR adjacent to the nozzle NZ. The first inductive heating coil IC1 may directly heat the crucible CR via a magnetic field generated when a current is applied. The first inductive heating coil IC1 may include a cooling passage COL2. Cooling water introduced through the cooling passage COL2 may lower a temperature, of the first inductive heating coil IC1, which may increase as the crucible CR is inductively heated. Accordingly, it may be possible to prevent the first inductive heating coil IC1 from being excessively heated.

The first inductive heating coil IC1 may be spaced apart from the crucible CR, and surround lateral side surfaces SS1, SS2, SS3, and SS4 of the crucible CR. The first inductive heating coil IC1 may be integrally spaced apart from the crucible CR, and surround the lateral side surfaces SS1, SS2, SS3, and SS4 of the crucible CR. The crucible CR may be heated via the first inductive heating coil; a shape of the first inductive heating coil is not limited to any one embodiment. For example, the first inductive heating coil may be provided in a plurality of parts spaced apart from each other, and surround one lateral side surface of the crucible CR. The detailed description thereof will be described later.

The first insulating member IM1 may be disposed between the first inductive heating coil IC1 and the crucible CR. The first insulating member IM1 may be in contact with one side surface of the first inductive heating coil IC1, and the second insulating member IM2 may be in contact with another opposed side surface of the first inductive heating coil IC1. The first insulating member IM1 may include ceramic. The first insulating member IM1 may perform an electrical insulation function and a heat shielding function between the first inductive heating coil IC1 and the crucible CR. The second insulating member IM2 may include teflon. The second insulating member IM2 blocks heat spreading outside of the crucible CR from being transferred to components of the equipment for manufacturing the electronic apparatus, which is disposed adjacent to the components, and thus it may be possible to prevent damage to the components.

The shielding member SC may be in contact with the second insulating member IM2. The shielding member SC may include a magnetic material. For example, the shielding member SC may include a ferrite core. Accordingly, the shielding member SC shields a magnetic field generated from the first inductive heating coil IC1, and thus it may be possible to prevent other components other than the crucible CR from being inductively heated.

The cooling jacket CJ may be in contact with the shielding member SC. The cooling jacket CJ may include a cooling passage COL1. That is, the cooling passage COL1 may be accommodated in the cooling jacket CJ. The cooling jacket CJ may lower a temperature, of the shielding member SC, which may increase as the crucible CR is inductively heated. Accordingly, it may be possible to prevent the shielding member SC from being excessively heated, and to stably maintain a shielding performance of the shielding member SC.

Referring to FIGS. 3 and 5 together, the second heater module HM2 may be spaced apart from the first heater module HM1, and be disposed below the first heater module HM1. The second heater module HM2 may heat a region of the crucible CR, which does not overlap with the first heater module HM1 when viewed from the first direction DR1 or the second direction DR2. The second heater module HM2 may include a heater HT and a heater frame HF. The heater HT may be accommodated in the heater frame HF and heat at least a part of the crucible CR.

The second heater module HM2 may include a resistive heating coil IC2. The resistive heating coil IC2 may be located to be spaced relatively farther apart from the nozzle NZ than the inductive heating coil IC1. The resistive heating coil IC2 may be a resistive type heating coil different from the inductive heating coil IC1 and heat a lower region, of the crucible CR, which is relatively farther away from the nozzle NZ.

The resistive heating coil IC2 may be divided into three regions PT1, PT2, and PT3, which are independently controlled. That is, a temperature of the crucible CR corresponding to each of the three regions PT1, PT2, and PT3 may be independently controlled. When a current is applied to the resistive heating coil included in the second heater module HM2, generated heat is transferred to the crucible CR, so that the crucible CR may be heated. The second heater module HM2 may be separately designed as a heater which includes a resistive heating coil. This may make it possible to adjust a temperature to be more uniformly distributed between a central portion and a periphery portion of the crucible CR. Therefore, a temperature uniformity inside the crucible CR may be improved.

The first reflector RF1 may be disposed between the first heater module HM1 and the second heater module HM2. The first reflector RF1 may prevent heat generated from the second heater module HM2 from being transferred toward a direction of the first heater module HM1 (or a third direction DR3). That is, the first reflector RF1 may control a movement direction of the heat generated from the second heater module HM2 to prevent the first heater module HM1 from being heated unnecessarily.

In an embodiment of the inventive concept, the temperature controller TP may further include a temperature measurement unit TC, a cooling chamber CC, and a second reflector RF2.

The temperature measurement unit TC may include a first temperature measurement unit TC1, and a second temperature measurement unit TC2. The first temperature measurement unit TC1 may be in contact with the crucible CR to measure a temperature of the crucible CR, and the second temperature measurement unit TC2 may be in contact with the heater frame HF of the second heater module HM2 to measure a temperature of the second heater module HM2. The first temperature measurement unit TC1 may be in direct contact with the crucible CR to directly measure a temperature of the crucible CR, and thus it may be possible to precisely control the temperature of the crucible CR to a target temperature.

The cooling chamber CC may accommodate the crucible CR, the first heater module HM1, and the second heater module HM2. The cooling chamber CC may lower temperatures of components accommodated in the cooling chamber CC to protect the components against heat sources.

The second reflector RF2 may be disposed between the cooling chamber CC and the second heater module HM2. The second reflector RF2 reflects or blocks a heat emitted in a direction from the second heater module HM2 to the cooling chamber CC, and thus it may be possible to prevent the cooling chamber CC from being heated unnecessarily.

Also, the equipment for manufacturing an electronic apparatus EA according to an embodiment of the inventive concept may further include a support member SL, a fixing pin PIN, a third reflector RF3, and an angle restriction plate AP.

The support member SL may be disposed under the first heater module HM1 and support the first heater module HM1.

The fixing pin PIN may be disposed on the support member SL and pass through at least a part of the first heater module HM1 to fix the first heater module HM1 to the support member SL. The support member SL is coupled to the first heater module HM1 via the fixing pin PIN such that a spacing distance between the first inductive heating coil IC1 of the first heater module HM1 and the crucible CR may be maintained at a desired distance.

The third reflector RF3 may be disposed in an inner space of the chamber CH. The third reflector RF3 is disposed in a region adjacent to the substrate BS and the mask MS, and thus it may be possible to prevent heat generated from the first heater module HM1 and the second heater module HM2 from being transferred toward a direction of the substrate BS and the mask MS. A nozzle hole NZH through which the nozzle NZ penetrates may be defined in the third reflector RF3, and the deposition material EM may penetrate the third reflector RF3 through the nozzle NZ and be sprayed onto the substrate BS.

The angle restriction plate AP may be disposed above the third reflector RF3. The angle restriction plate AP adjusts a spraying direction for the deposition material EM which is sprayed by the nozzle NZ, and thus it may be possible to induce the deposition material EM to move in a desired direction. FIG. 3 illustrates that the angle restriction plate AP is connected to the cooling chamber CC, but an arrangement position of the angle restriction plate AP may be changed as long as the angle restriction plate AP may adjust a spraying direction or a spraying angle for the deposition material EM which is sprayed by the nozzle NZ.

A flange MT, the mask MS, and the base substrate BS may be disposed in the inner space of the chamber CH in addition to the crucible CR and the temperature controller TP which are described above.

The flange MT may be disposed on a side wall of the chamber CH and support the mask MS. However, an embodiment of the inventive concept is not limited thereto, and a shape, a position, and the number of the flange MT are not limited to any one embodiment as long as the flange MT may support the mask MS.

The mask MS may be supported by the flange MT and include a plurality of deposition holes MS-OP so as for the deposition material EM to be passed. However, when the deposition material EM is deposited on the base substrate BS without a separate pattern, the mask MS may be omitted.

The base substrate BS may be a mother substrate to be deposited. The base substrate BS may be applied with the deposition material EM which is provided from the crucible CR.

Referring to FIGS. 5 and 6, the crucible CR may include two long lateral side surfaces SS1 and SS2 facing each other, and two short lateral side surfaces SS3 and SS4 facing each other. The first inductive heating coil IC1 may be located spaced apart from the crucible CR, and surround the lateral side surfaces SS1, SS2, SS3, and SS4 of the crucible CR.

A first spacing distance d1 from each of the long lateral side surfaces SS1 and SS2 to the first heater module HM1 may be constant in a vertical direction (the second direction DR2 or a direction opposed to the second direction DR2) with respect to each of the long lateral side surfaces SS1 and SS2. A second spacing distance d2 from each of the short lateral side surfaces SS3 and SS4 to the first heater module HM1 may be constant in a vertical direction (the first direction DR1 or a direction opposed to the first direction DR1) with respect to each of the short lateral side surfaces SS3 and SS4.

In this case, the second spacing distance d2 may be greater than the first spacing distance d1. For example, the first spacing distance d1 may be about 7.5 mm, and the second spacing distance d2 may be about 17.5 mm. In a region adjacent to the short lateral side surfaces SS3 and SS4, the first inductive heating coil IC1 may be disposed more densely, and thus inductive heating performed in the region may be relatively stronger. According to the inventive concept, since the second spacing distance d2 is designed to be greater than the first spacing distance d1, heat may be prevented from being excessively concentrated on the short lateral side surfaces SS3 and SS4 on which the inductive heating coils are densely disposed, and thus it may be possible to uniformly heat all the lateral side surfaces of the crucible CR.

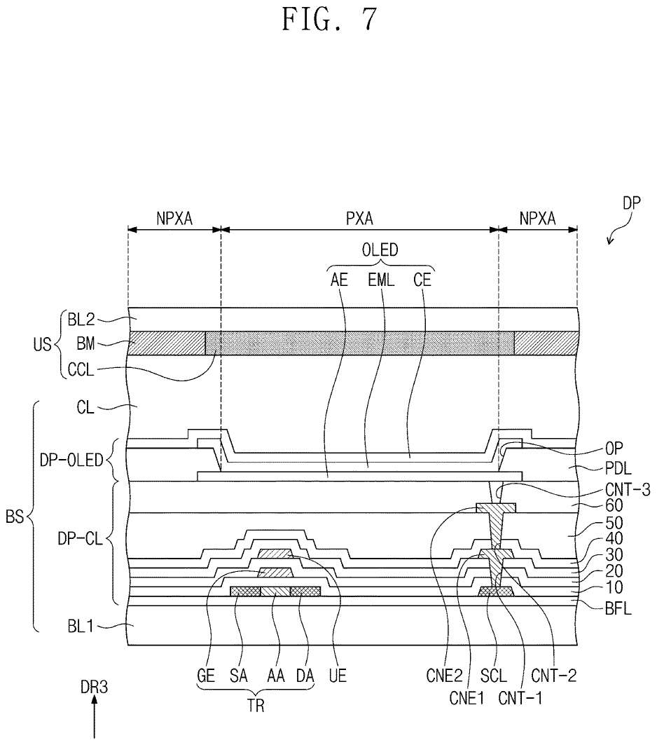

FIG. 7 is a cross-sectional view of a display panel according to an embodiment of the inventive concept. Some components of a display panel DP illustrated in FIG. 7 may be manufactured by the deposition equipment ED described in FIG. 3. For example, the base substrate BS described in FIG. 3 may correspond to a base substrate BS of the display panel DP.

The display panel may include the base substrate BS and an upper substrate US.

The display panel DP may include a light-emitting region PXA and a non-light emitting region NPXA. The light-emitting region PXA may be a region in which light provided from a light-emitting element OLED is emitted. The display panel DP may include a plurality of insulating layers, a semiconductor pattern, a conductive pattern, a signal line, and the like. An insulating layer, a semiconductor layer, and a conductive layer are provided through coating, deposition, and the like. Thereafter, the insulating layer, the semiconductor layer, and the conductive layer may be selectively patterned by performing photolithography and etching. In this manner, the semiconductor pattern, the conductive pattern, the signal line, and the like, which are included in a circuit element layer DP-CL and a display element layer DP-OLED, may be provided.

The base substrate BS may include a first base layer BL1, the circuit element layer DP-CL, the display element layer DP-OLED, and a cover layer CL which are sequentially stacked.

The first base layer BL1 may include a glass substrate, a sapphire substrate, a plastic film, or an organic/inorganic stacked film. The first base layer BL1 may have a single-or multi-layered structure. For example, the first base layer BL1 may have either a structure in which a plurality of plastic films bonded to each other via adhesives are stacked, or a structure in which a glass substrate and a plastic film bonded to each other via an adhesive are stacked. The first base layer BL1 may have flexibility. For example, the first base layer BL1 may include polyimide. However, this is illustrated as an example. The first base layer BL1 may also be provided in a rigid state and is not limited to any one embodiment.

A buffer layer BFL may be disposed on the first base layer BL1. The buffer layer BFL may improve a bonding force between the first base layer BL1 and a semiconductor pattern. The buffer layer BFL may include a silicon oxide layer and a silicon nitride layer.

The semiconductor pattern may be disposed on the buffer layer BFL. The semiconductor pattern may include polysilicon. However, an embodiment of the inventive concept is not limited thereto, and the semiconductor pattern may include amorphous silicon or a metal oxide.

A transistor TR may be disposed on the buffer layer BFL. A source SA, an active AA, and a drain DA of the transistor TR may be provided from the semiconductor pattern.

A first insulating layer 10 to a sixth insulating layer 60 may be sequentially disposed on the buffer layer BFL. The first insulating layer 10 to the sixth insulating layer 60 may each be an inorganic layer or an organic layer.

A gate electrode GE may be disposed on the first insulating layer 10. An upper electrode UE may be disposed on the second insulating layer 20. A first connection electrode CNE1 may be disposed on the third insulating layer 30. The first connection electrode CNE1 may be connected to a connection signal line SCL via a contact hole CNT-1 which penetrates through the first insulating layer 10 to the third insulating layer 30.

A second connection electrode CNE2 may be disposed on the fifth insulating layer 50. The second connection electrode CNE2 may be connected to the first connection electrode CNE1 via a contact hole CNT-2 which penetrates through the fourth insulating layer 40 and the fifth insulating layer 50.

The display element layer DP-OLED may include a pixel-defining film PDL and the light-emitting element OLED.

The pixel-defining film PDL may be disposed on the sixth insulating layer 60. A light-emitting opening OP may be defined (or be included) in the pixel-defining film PDL. The light-emitting opening OP may correspond to an anode AE, and the pixel-defining film PDL may expose at least a part of the anode AE via the light-emitting opening OP.

The pixel-defining film PDL may include an inorganic insulating material. For example, the pixel-defining film PDL may include silicon nitride.

The light-emitting element OLED may include the anode AE, a light-emitting layer EML, and a cathode CE.

The anode AE may be disposed on the sixth insulating layer 60. The anode AE may be connected to the second connection electrode CNE2 via a contact hole CNT-3 which penetrates through at least a portion of the sixth insulating layer 60. The anode AE may be a transmissive electrode, a transflective electrode, or a reflective electrode. The anode AE may have a single-or multi-layered structure. The anode AE may include a plurality of layers containing ITO and Ag. For example, the anode AE may include an ITO-containing layer (hereinafter, a lower ITO layer), an Ag-containing layer (hereinafter, an Ag layer) disposed on the lower ITO layer, and an ITO-containing layer (hereinafter, an upper ITO layer) disposed on the Ag layer. However, an embodiment of the inventive concept is not limited thereto, and the anode AE may also be provided to have a single-layered structure.

The light-emitting layer EML may be disposed on the anode AE. Also, the light-emitting layer EML may be referred to as an ‘organic layer’ or an ‘intermediate layer’. The light-emitting layer EML may cover a part of an upper surface of the pixel-defining film PDL.

The cathode CE may be disposed on the light-emitting layer EML. The cathode CE may cover the light-emitting layer EML. The cathode CE may be disposed on the light-emitting layer EML in common.

Although not illustrated, a hole control layer may be disposed between the anode AE and the light-emitting layer EML, and an electronic control layer may be disposed between the light-emitting layer EML and the cathode CE.

The cover layer CL may be disposed on the cathode CE. The cover layer CL may include a plurality of thin films. For example, the cover layer CL may include a protective layer for protecting a light-emitting element. The cover layer CL may include a thin-film encapsulation layer including an inorganic layer/an organic layer/an inorganic layer.

The upper substrate US may include a black matrix layer BM, a color control layer CCL, and a second base layer BL2.

The color control layer CCL and the black matrix layer BM may be disposed on the cover layer CL. The color control layer CCL may transmit first color light or convert the first color light into second color light or third color light according to a color of light provided from the light-emitting element OLED. The color control layer CCL may include quantum dots.

The black matrix layer BM may overlap the non-light emitting region NPXA. The black matrix layer BM may include a light-absorbing material and is not limited to including any one material.

The second base layer BL2 may be located to be spaced apart from the cover layer CL. The second base layer BL2 may be any one of a glass substrate, a plastic substrate, or a polyimide (PI)-containing substrate.

The deposition equipment ED (see FIG. 3) according to the inventive concept may be used during a deposition process among steps of forming the display panel DP. For example, the deposition equipment ED may be used for depositing at least one of inorganic layers included in the fifth insulating layer 50, the sixth insulating layer 60, the light-emitting layer EML, and the cover layer CL. The deposition equipment ED may be used during a deposition process of the light-emitting layer EML, and in this case, the mask MS (see FIG. 3) may be a fine metal mask (FMM). In an embodiment, the deposition equipment may be used during the deposition process of the cover layer CL, and in this case, the mask may be an open mask. Different deposition materials may be used according to a material of each of the inorganic layers included in the fifth insulating layer 50, the sixth insulating layer 60, the light-emitting layer EML, and the cover layer CL, and the components may each be provided independently by an independent deposition equipment. However, an embodiment of the inventive concept is not limited thereto. A component provided through a deposition process among the components provided in the display panel DP may be manufactured by the deposition equipment ED according to the inventive concept and is not limited to any one embodiment.

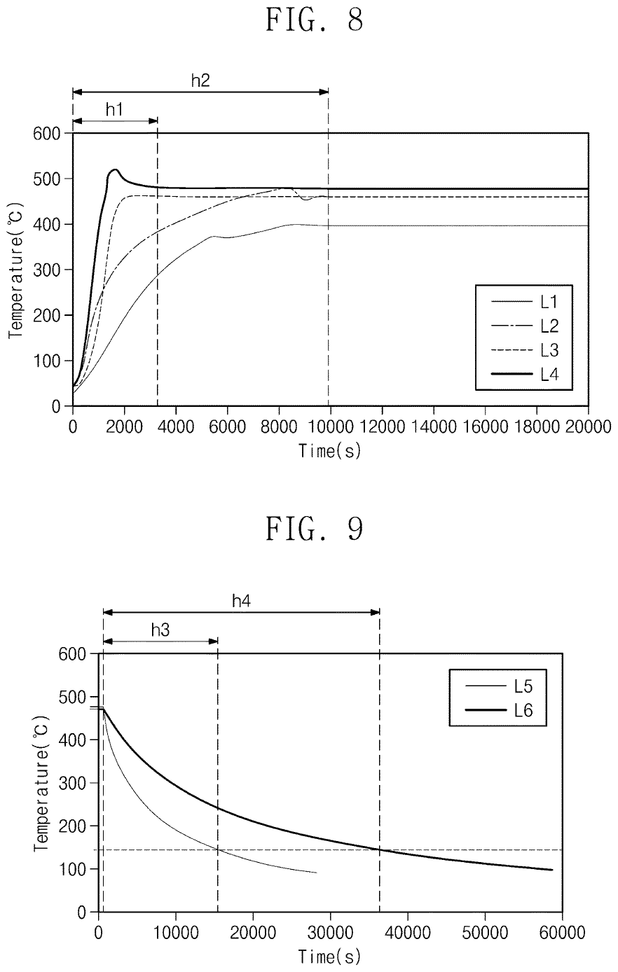

FIG. 8 is a graph showing a temperature increase rate of the crucible CR (see FIG. 3) according to an embodiment and a comparative embodiment of the inventive concept. FIG. 9 is a graph showing a temperature decrease rate of the crucible CR according to an embodiment and a comparative embodiment of the inventive concept.

FIG. 8 illustrates four curved lines L1, L2, L3, and L4 showing temperature increase rates when the crucible CR is heated with a resistive type heater and an inductive heating type heater. The first curved line L1 and the second curved line L2 show temperature increase rates of the crucible according to a comparative embodiment, and the third curved line L3 and the fourth curved line L4 show temperature increase rates of the crucible according to an embodiment of the inventive concept. Specifically, the first curved line L1 shows a temperature increase rate measured at a lower part of the crucible CR when the crucible CR is heated with a resistive type heater. The second curved line L2 shows a temperature increase rate measured at an upper part of the crucible CR when the crucible CR is heated with a resistive type heater. The third curved line L3 shows a temperature increase rate measured at a lower part of the crucible CR when the crucible CR is heated with an inductive heating type heater. The fourth curved line L4 shows a temperature increase rate measured at an upper part of the crucible CR when the crucible CR is heated with an inductive heating type heater.

As illustrated in FIG. 8, when the crucible CR is heated with an inductive heating type heater, a temperature increase rate of the crucible CR may be greater than that of the crucible CR when a resistive type heater is used. Specifically, a time h2 to heat the crucible CR to a target temperature when a resistive type heater is used may be at least two times greater than a time h1 to heat the crucible CR to a target temperature when an inductive heating type heater is used. That is, a rate that the temperature of the crucible CR increases when an inductive heating type heater is used may be at least two times greater than a rate that the temperature of the crucible CR increases when a resistive type heater is used.

FIG. 9 illustrates curved lines respectively showing temperature decrease rates after the crucible CR is heated with a resistive type heater and an inductive heating type heater. A fifth curved line L5 shows a temperature decrease rate of the crucible according to a comparative embodiment, and a sixth curved line L6 shows a temperature decrease rate of the crucible according to an embodiment of the inventive conceptive.

As illustrated in FIG. 9, when the crucible CR is heated with an inductive heating type heater, a temperature decrease rate may be greater than that when a resistive type heater is used. Specifically, a time h4 to cool down, to a target temperature, the crucible CR heated by using a resistive type heater may be at least two times greater than a time h3 to cool down, to a target temperature, the crucible CR heated by using an inductive heating type heater. The time taken in this case may be measured as a natural temperature decrease time under the same conditions without using a separate cooling apparatus. That is, a rate that the temperature of the crucible CR heated by using an inductive heating type heater decreases may be at least two times greater than a rate of temperature decrease of the crucible CR heated by using a resistive type heater.

When the crucible CR is heated by using only a resistive type heater, the crucible CR may be indirectly heated by a radiant heat emitted from a heater while a temperature of the crucible CR increases. That is, the crucible CR may not be directly heated by heat generated from the heater, but be heated by radiant heat which is emitted from the heater and transferred to the crucible CR. Accordingly, a temperature increase rate of the crucible CR may slow down compared to the rate of increase when the crucible CR is directly heated. Additionally, while a temperature decreases, residual heat of a resistive type heater is transferred to the crucible CR, which may increase the time it takes for the crucible CR to be cooled down to a target temperature.

According to the inventive concept, at least a part of the crucible CR may be directly heated by using a first heater module HM1 which includes a first inductive heating coil IC1. Since the first heater module HM1 is disposed around the crucible CR, the crucible CR may be directly heated by induction, and thus it may be possible to improve the temperature increase rate and the temperature decrease rate of the crucible CR. Therefore, a temperature control accuracy of the crucible CR may be improved, and productivity of a deposition process may be enhanced.

Furthermore, since the crucible CR is directly heated, heat transferred to the reflector RF3 (see FIG. 3) and the angle restriction plate AP (see FIG. 3), which are disposed adjacent to the nozzle, may be relatively reduced, and thus the overall temperature of an inner space of the chamber CH may also decrease. In this manner, heat transferred to the substrate BS (see FIG. 3) may be reduced to inhibit a temperature of the substrate BS from increasing, and thus a deposition quality may be improved.

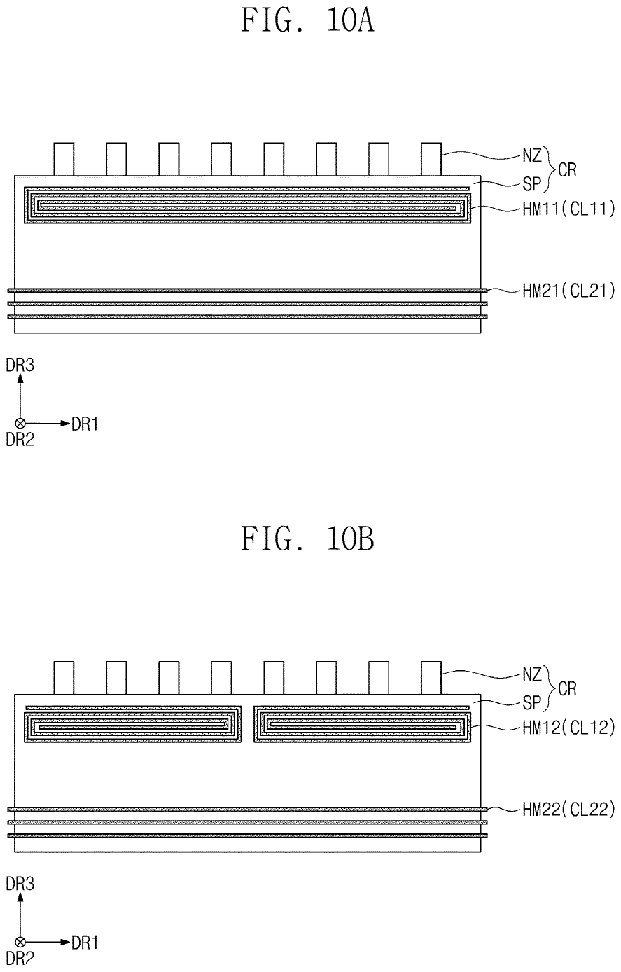

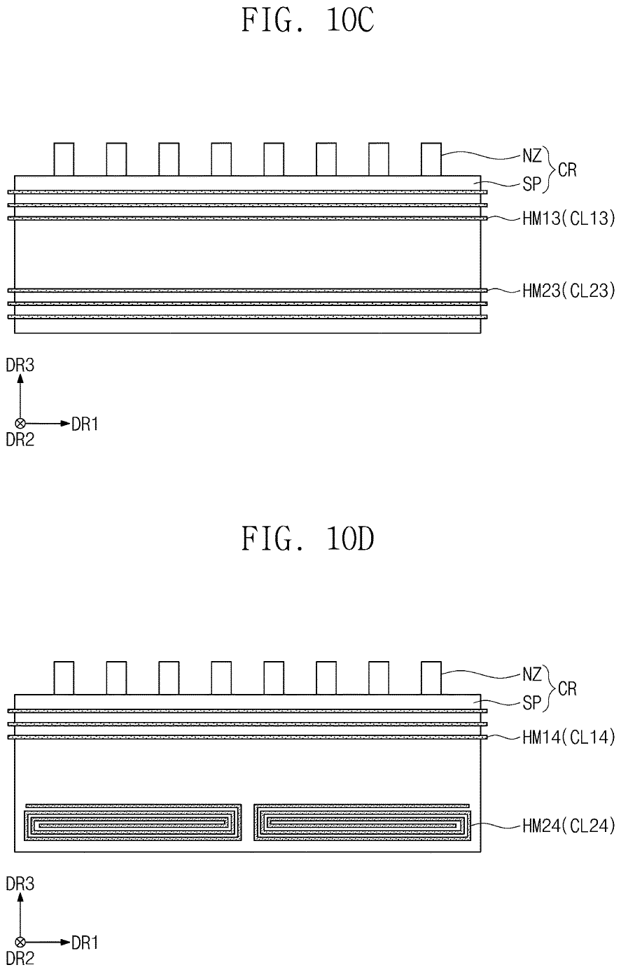

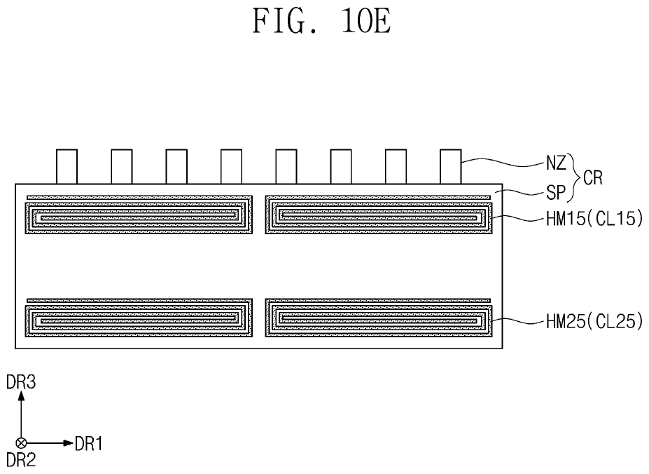

FIG. 10A is a schematic view describing an arrangement of coils in an equipment for manufacturing an electronic apparatus according to an embodiment of the inventive concept. FIG. 10B is a schematic view describing an arrangement of coils in an equipment for manufacturing an electronic apparatus according to an embodiment of the inventive concept. FIG. 10C is a schematic view describing an arrangement of coils in an equipment for manufacturing an electronic apparatus according to an embodiment of the inventive concept. FIG. 10D is a schematic view describing an arrangement of coils in an equipment for manufacturing an electronic apparatus according to an embodiment of the inventive concept. FIG. 10E is a schematic view describing an arrangement of coils in an equipment for manufacturing an electronic apparatus according to an embodiment of the inventive concept. For ease of description, FIGS. 10A to 10E illustrate only coils among components of a first heater module and a second heater module.

Referring to FIG. 10A, a first heater module HM11 may include a first inductive heating coil CL11, and a second heater module HM21 may include a second inductive heating coil CL21.

The first inductive heating coil CL11 may be disposed adjacent to a nozzle NZ. The first inductive heating coil CL11 may heat an upper region of a crucible CR adjacent to the nozzle. The first inductive heating coil CL11 may be disposed on some part of lateral side surfaces of the crucible CR. Specifically, the first inductive heating coil CL11 may be disposed adjacent to the long lateral side surfaces SS1 and SS2 (see FIG. 6) of the crucible CR. The first inductive heating coil CL11 may be disposed on some part of the lateral side surfaces of the crucible CR. In this manner, since the coil is disposed along the long lateral side surfaces SS1 and SS2 which have relatively large areas, excellent thermal efficiency may be secured. However, an embodiment is not limited thereto, and the first inductive heating coil CL11 may also be disposed adjacent to the short lateral side surfaces SS3 and SS4 (see FIG. 6) of the crucible CR.

The second inductive heating coil CL21 may surround lateral side surfaces of the crucible CR. The second inductive heating coil CL21 may be located to be spaced relatively farther apart from the nozzle NZ than the first inductive heating coil CL11. The second inductive heating coil CL21 may heat a lower region close to a bottom, of the crucible CR, which is relatively farther away from the nozzle NZ.

The first inductive heating coil CL11 may have a spiral shape of extending from a center of the coil in a transverse direction. In this embodiment, a spiral shape of extending in a transverse direction may correspond to a shape in which the center of the coil is parallel to the first direction DR1 or the second direction DR2. That is, the first inductive heating coil CL11 may be provided to have a spiral shape such that the center of the first inductive heating coil CL11 is parallel to the second direction DR2 and the first inductive heating coil CL11 extends on a plane defined by the first direction DR1 and the third direction DR3.

The second inductive heating coil CL21 may have a spiral shape of extending from a center of the coil in a longitudinal direction. In this embodiment, a spiral shape of extending in a longitudinal direction may correspond to a shape in which a center of the coil is parallel to the third direction DR3. That is, the second inductive heating coil CL21 may be provided to have a spiral shape such the center of the second inductive heating coil CL21 is parallel to the third direction DR3 and the second inductive heating coil CL21 extends on a plane defined by the first direction DR1 and the second direction DR2.

The first heater module HM11 and the second heater module HM21 may each be independently controlled. This may make it possible to further uniformly adjust a temperature distribution between a center and a periphery of the crucible CR.

Arrangement positions of first inductive heating coils CL12, CL13, CL14, and CL15 and second inductive heating coils CL22, CL23, CL24, and CL25, which will be described with reference to FIGS. 10B to 10E below, may correspond to the first inductive heating coil CL11 illustrated in FIG. 10A when the coils have a spiral shape of extending in a transverse direction, and may correspond to the second inductive heating coil CL21 illustrated in FIG. 10A when the coils have a spiral shape of extending in a longitudinal direction, and thus hereinafter, the description thereof will be omitted.

Referring to FIG. 10B, a first heater module HM12 may include the first inductive heating coil CL12, and a second heater module HM22 may include the second inductive heating coil CL22. The first inductive heating coil CL12 may have a spiral shape of extending from a center of the coil in a transverse direction, and the second inductive heating coil CL22 may have a spiral shape of extending from a center of the coil in a longitudinal direction.

Unlike an embodiment described with reference to FIG. 10A, in this embodiment, the first inductive heating coil CL12 includes a plurality of coils, which may be independently controlled. In this case, since the plurality of coils are independently controlled, a temperature of the crucible CR may be more uniformly controlled than that of the crucible CR when a single coil is used.

Referring to FIG. 10C, a first heater module HM13 may include the first inductive heating coil CL13, and a second heater module HM23 may include the second inductive heating coil CL23. The first and second inductive heating coils CL13 and CL23 may have a spiral shape of extending from a center of each of the coils in a longitudinal direction.

Unlike embodiments described with reference to FIGS. 10A and 10B, in this embodiment, the first inductive heating coil CL13 may also have a spiral shape of extending from a center of the coil in a longitudinal direction, and entirely surround lateral side surfaces of the crucible CR. Accordingly, output generated from the first and second inductive heating coils CL13 and CL23 may be uniformly distributed on the entire lateral side surface of the crucible CR, and thus excellent thermal efficiency may be secured. Furthermore, since the coils are more easily arranged than that extending in a transverse direction, it may be possible to enhance the degree of freedom in designing the coils.

Referring to FIG. 10D, a first heater module HM14 may include the first inductive heating coil CL14, and a second heater module HM24 may include the second inductive heating coil CL24. The first inductive heating coil CL14 may have a spiral shape of extending from a center of the coil in a longitudinal direction, and the second inductive heating coil CL24 may have a spiral shape of extending from a center of the coil in a transverse direction.

The second inductive heating coil CL24 includes a plurality of coils, which may be independently controlled. In this case, since the plurality of coils are independently controlled, a temperature of the crucible CR may be more uniformly controlled than that of the crucible CR when a single coil is used.

Referring to FIG. 10E, a first heater module HM15 may include the first inductive heating coil CL15, and a second heater module HM25 may include the second inductive heating coil CL25. The first and second inductive heating coils CL15 and CL25 may have a spiral shape of extending from a center of each of the coils in a transverse direction. The first heater module HM15 and the second heater module HM25 each include a plurality of coils, which may be independently controlled. In this case, since the plurality of coils are independently controlled, a temperature of the crucible CR may be more uniformly controlled than that of the crucible CR when a single coil is used.

According to the above-described embodiments, temperature distribution of the crucible CR may be more uniformly controlled due to an arrangement of the heater module and the coil, and independent control of the coils, and thus it may be possible to improve productivity of a deposition process. However, an embodiment of the inventive concept is not limited to the embodiments described with reference to FIGS. 10A to 10E, and shapes, an arrangement, and heating methods of the coils may be variously changed according to a design intent.

According to the inventive concept, a crucible CR may be directly heated by using an inductive heating type heater. Accordingly, a temperature increase rate and a temperature decrease rate of the crucible CR may be effectively improved compared to those of a crucible indirectly heated by radiant heat. Additionally, a temperature of the crucible CR may be more precisely adjusted by providing a plurality of heater modules HM1 and HM2, which are independently controlled. Accordingly, a temperature uniformity inside the crucible CR may be improved, and a deposition material may be uniformly evaporated and evenly deposited on a substrate. Therefore, a display panel may have an improved quality, and a productivity during a deposition process may also be enhanced.

According to the inventive concept, a crucible is directly heated by using an inductive heating type heater, and thus a temperature increase rate and a temperature decrease rate of the crucible may be effectively improved compared to those of a crucible indirectly heated by radiant heat.

Additionally, a temperature of the crucible may be more precisely adjusted by providing a plurality of heaters for heating a crucible, which are independently controlled. Accordingly, a temperature uniformity inside the crucible may be improved, and a deposition material may be evenly deposited on a substrate. Therefore, a display panel may have an improved quality, and a productivity during a deposition process may also be enhanced.

In the above, description has been made with reference to embodiments of the inventive concept, but those skilled or of ordinary skill in the art may understand that various modifications and changes may be made to the inventive concept insofar as such modifications and changes do not depart from the spirit and technical scope of the inventive concept set forth in the claims to be described later. Therefore, the technical scope of the inventive concept is not to be limited to the contents stated in the detailed description of the specification, but should be determined by the claims.

What is claimed is:

1. An equipment for manufacturing an electronic apparatus comprising:
a chamber configured to provide an inner space;
a crucible disposed in the inner space, and including a storage unit configured to store a deposition material, and a nozzle configured to spray the deposition material; and
a temperature controller configured to control a temperature of the crucible,
wherein the temperature controller includes,
a first heater module including a first inductive heating coil and configured to heat at least a part of the crucible,
a second heater module disposed below the first heater module and on a lateral side surface of the crucible and configured to heat another part of the crucible, and
a first reflector which is disposed between the first heater module and the second heater module.

2. The equipment of claim 1, wherein the temperature controller further comprises a temperature measurement unit which is in contact with the crucible and measures the temperature of the crucible.

3. The equipment of claim 1, wherein the crucible comprises two long lateral side surfaces facing each other and two short lateral side surfaces facing each other,
a first spacing distance from each of the long lateral side surfaces to the first heater module is constant in a first direction and
a second spacing distance from each of the short lateral side surfaces to the first heater module is constant in a second direction.

4. The equipment of claim 3, wherein the second spacing distance is greater than the first spacing distance.

5. The equipment of claim 3, further comprising:
a support member configured to support the first heater module; and
a fixing pin configured to fix the first heater module to the support member.

6. The equipment of claim 1, wherein the temperature controller further comprises a cooling chamber which accommodates the crucible, the first heater module, and the second heater module, and
a second reflector disposed between the cooling chamber and the second heater module.

7. The equipment of claim 1, further comprising:
a third reflector disposed in the inner space, and having a nozzle hole through which the nozzle penetrates; and
an angle restriction plate configured to adjust a spraying angle of the deposition material sprayed from the nozzle.

8. The equipment of claim 1, wherein the first heater module comprises a first insulating member in contact with a first lateral side surface of the first inductive heating coil,
a second insulating member in contact with a second lateral side surface opposed to the first lateral side surface of the first inductive heating coil,
a shielding member in contact with the second insulating member, and
a cooling jacket including a first cooling passage, and the cooling jacket being in contact with the shielding member, and
the first inductive heating coil comprising a second cooling passage.

9. The equipment of claim 1, wherein the second heater module comprises a resistive heating coil, and
the resistive heating coil is divided into three regions, which are independently controlled.

10. The equipment of claim 9, wherein the first inductive heating coil has a spiral shape extending in a longitudinal direction from a center of the first inductive heating coil.

11. The equipment of claim 9, wherein the first inductive heating coil has a spiral shape extending in a transverse direction from a center of the first inductive heating coil.

12. The equipment of claim 11, wherein the first inductive heating coil comprises a plurality of coils, which are independently controlled.

13. The equipment of claim 1, wherein the second heater module comprises a second inductive heating coil, and
the first inductive heating coil and the second inductive heating coil have a spiral shape extending in a longitudinal direction from a center of each of the coils.

14. The equipment of claim 1, wherein the second heater module comprises a second inductive heating coil,
the first inductive heating coil has a spiral shape extending in a longitudinal direction from a center of the first inductive heating coil,
the second inducive heating coil has a spiral shape extending in a transverse direction from a center of the second inductive heating coil,
the second inductive heating coil includes plurality of coils, which are independently controlled.

15. The equipment of claim 1, wherein the second heater module comprises a second inductive heating coil,
the first inductive heating coil and the second inductive heating coil have a spiral shape extending in a transverse direction from a center of each of the coils,
the first heater module and the second heater module each comprising a plurality of coils, which are independently controlled.

16. An equipment for manufacturing an electronic apparatus comprising:
a chamber configured to provide an inner space;
a crucible including a storage unit which stores a deposition material, and a nozzle which sprays the deposition material;
a heating unit including a heater which applies heat to the deposition material;
a cooling unit configured to alleviate an increase in a temperature of the inner space due to the heat; and
an angle restriction plate configured to adjust a deposition region of the deposition material,
wherein the heating unit includes a first heater module, a reflector, and a second heater module which are arranged in that sequence on one side of the crucible along a direction toward a lower side of the crucible, and
the first heater module including a first inductive heating coil.

17. The equipment of claim 16, wherein the second heater module comprises a second inductive heating coil, and
the first inductive heating coil and the second inductive heating coil have a spiral shape extending in a longitudinal direction from a center of each of the coils.

18. The equipment of claim 16, wherein the second heater module comprises a second inductive heating coil,
the first inductive heating coil has a spiral shape extending in a longitudinal direction from a center of the first inductive heating coil, and
the second inductive heating coil has a spiral shape extending in a transverse direction from a center of the second inductive heating coil.

19. The equipment of claim 16, wherein the second heater module comprises a second inductive heating coil which is disposed on one lateral side surface of the crucible, and
each of the first inductive heating coil and the second inductive heating coil has a spiral shape extending in a transverse direction from a center of each of the coils.

20. An electronic apparatus comprising:
a display module including a substrate, a display element layer, and a circuit element layer, the display element layer and circuit element layer being disposed in that sequence on the substrate; and
one or more processors configured to provide image data to the display module,
wherein at least some portion of the display element layer and the circuit element layer are manufactured by deposition equipment,
wherein the deposition equipment includes,
a chamber configured to provide an inner space,
a crucible disposed in the inner space and including a storage unit configured to store a deposition material, and a nozzle configured to spray the deposition material, and
a temperature controller configured to control a temperature of the crucible,
wherein the temperature controller includes,
a first heater module including a first inductive heating coil and configured to heat at least a part of the crucible,
a second heater module disposed below the first heater module and on a side surface of the crucible and configured to heat another part of the crucible, and
a reflector which is disposed between the first heater module and the second heater module.
